(19) United States
(12) Patent Application Publication
(10) Pub. No.: US 2025/0151300 A1
(43) Pub. Date: May 8, 2025

(54) SEMICONDUCTOR DEVICE

(71) Applicant: Mitsubishi Electric Corporation, Tokyo (JP)

(72) Inventors: Kenji SUZUKI, Tokyo (JP); Yuki HATA, Tokyo (JP); Shigeo TOI, Tokyo (JP); Hiromichi INENAGA, Tokyo (JP); Tomohito KUDO, Tokyo (JP)

(73) Assignee: Mitsubishi Electric Corporation, Tokyo (JP)

(21) Appl. No.: 18/825,044

(22) Filed: Sep. 5, 2024

(30) Foreign Application Priority Data
Nov. 7, 2023 (JP) 2023-190026

(51) Int. Cl. H01L 29/739; H01L 29/06; H01L 29/423; H01L 29/66

(52) U.S. Cl. CPC H10D 12/481; H10D 12/038; H10D 62/102; H10D 62/127; H10D 64/513

(57) ABSTRACT

A semiconductor device includes: an emitter layer and a contact layer that are provided in a surface portion of a base layer; a carrier storage layer provided between the base layer and a drift layer; and a trench reaching a position deeper than the carrier storage layer and having a gate electrode buried therein. A depth of the contact layer is deeper than that of the emitter layer. An impurity concentration of the carrier storage layer is 1.4E16/cm³ or less at least in a portion adjacent to the trench.

### BACKGROUND OF THE INVENTION

### Field of the Invention

The present disclosure relates to a semiconductor device.

### Description of the Background Art

There is a demand for reduction of a conduction loss and a switching loss of an insulated gate bipolar transistor (IGBT), for example, in order to reduce an inverter loss. Since a current flows in the IGBT in the vertical direction, it is effective to lower a resistance of a drift layer that holds a withstand voltage, and measures have been taken to optimize a cell structure such that carriers are likely to be stored during conduction. As a result, for example, Japanese Patent Application Laid-Open No. 2020-107707 below proposes an IGBT in which an N-type layer having an impurity concentration higher than that of a drift layer is provided between a base layer of a P type and the drift layer of an N-type to enhance a carrier storage effect. This N-type layer is called a carrier storage layer (CS layer).

When the carrier storage layer is provided in the IGBT as in Japanese Patent Application Laid-Open No. 2020-107707, an effect of reducing the collector-emitter saturation voltage Vce (sat) can be obtained, but there arises a problem that short-circuit tolerance decreases. The short-circuit tolerance is a length of time until a power device is broken when a load is short-circuited, and is one of electrical characteristics required for the IGBT. For example, even in a case where the load is short-circuited due to a malfunction or the like, a large current flows through the IGBT, and a gate voltage rises due to a displacement current, withstanding is required without being broken for several microseconds.

### SUMMARY

An object of the present disclosure is to improve short-circuit tolerance of a semiconductor device having a carrier storage layer.

A semiconductor device according to the present disclosure includes: a semiconductor substrate on which a drift layer of a first conductivity type is formed; a base layer of a second conductivity type provided in a surface portion on a first main surface side of the semiconductor substrate; an emitter layer of the first conductivity type which is selectively provided in the surface portion of the base layer and has an impurity concentration higher than that of the drift layer; a contact layer of the second conductivity type which is selectively provided in the surface portion of the base layer and has an impurity concentration higher than that of the base layer; a carrier storage layer of the first conductivity type which is provided between the base layer and the drift layer and has an impurity concentration higher than that of the drift layer; a trench which is provided on the first main surface side of the semiconductor substrate and reaches a position deeper than the carrier storage layer; a gate insulating film provided on an inner surface of the trench; a gate electrode provided on the gate insulating film and buried in the trench; and a collector layer of the second conductivity type provided in a surface portion on a second main surface side of the semiconductor substrate. A depth of the contact layer is deeper than that of the emitter layer, and an impurity concentration of the carrier storage layer is 1.4E16/cm³ or less at least in a portion adjacent to the trench.

According to the present disclosure, the short-circuit tolerance of the semiconductor device having the carrier storage layer is improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor device according to a first preferred embodiment;

FIG. 2 is a cross-sectional view of an IGBT according to the first preferred embodiment;

FIG. 3 is a view illustrating a relationship between an impurity concentration of a carrier storage layer and a collector-emitter saturation voltage;

FIG. 4 is a view illustrating a relationship between the impurity concentration of the carrier storage layer and a gate voltage immediately before a breakdown of the IGBT in a short-circuit state;

FIGS. 5 to 15 are views illustrating a manufacturing process of the IGBT according to the first preferred embodiment;

FIGS. 16 and 17 are cross-sectional views of RC-IGBTs according to modifications of the first preferred embodiment;

FIG. 18 is a cross-sectional view of an IGBT according to a modification of the first preferred embodiment;

FIG. 19 is a cross-sectional view of an IGBT according to a second preferred embodiment;

FIG. 20 is a cross-sectional view of an RC-IGBT according to a modification of the second preferred embodiment;

FIG. 21 is a cross-sectional view of an IGBT according to a third preferred embodiment; and

FIG. 22 is a cross-sectional view of an RC-IGBT according to a modification of the third preferred embodiment.

### DESCRIPTION OF THE PREFERRED EMBODIMENTS

Although description is given assuming that a first conductivity type is an N type and a second conductivity type is a P type in preferred embodiments below, conversely, the first conductivity type may be the P type, and the second conductivity type may be the N type. Further, an N type having a relatively high impurity concentration is denoted by “N⁺”, an N type having a relatively low impurity concentration is denoted by “N⁻”, a P type having a relatively high impurity concentration is denoted by “P⁺”, and a P type having a relatively low impurity concentration is denoted by “P⁻”. Here, a level of an impurity concentration of each region is defined by a peak concentration. That is, a region having a high (or low) impurity concentration means a region having a high (or low) peak concentration of impurities.

### First Preferred Embodiment

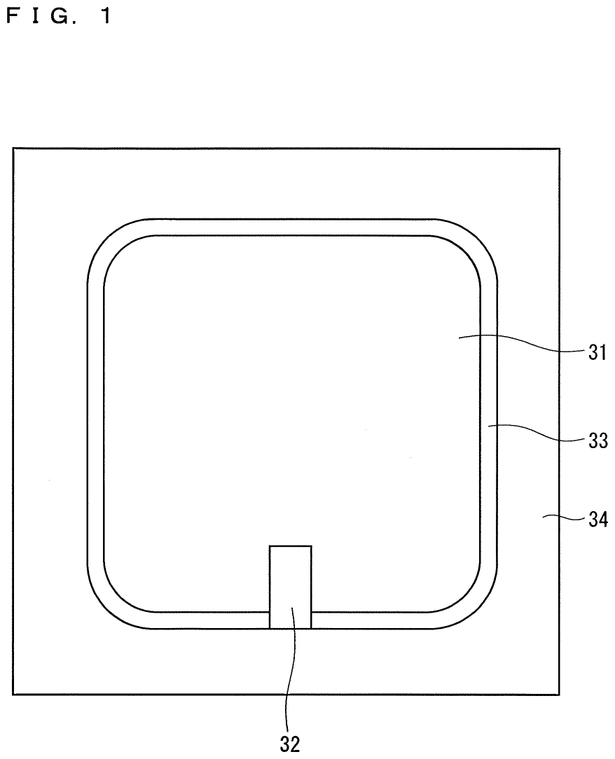

FIG. 1 is a top view of a semiconductor device according to a first preferred embodiment. In the first preferred embodiment, the semiconductor device includes a trench gate type IGBT as a semiconductor element.

As illustrated in FIG. 1, the semiconductor device according to the first preferred embodiment includes a cell region 31 in which a cell of an IGBT is disposed, a gate pad region 32 in which a gate pad of the IGBT is disposed, a gate wiring region 33 in which a gate wiring that connects a gate electrode of the IGBT and the gate pad is disposed, and a termination region 34 provided outside the cell region 31, the gate pad region 32, and the gate wiring region 33. An emitter pad of the IGBT is disposed on the cell region 31. In the termination region 34, a withstand voltage holding structure such as a field limiting ring (FLR) or variation of lateral doping (VLD) is appropriately provided according to a withstand voltage design required for the semiconductor device.

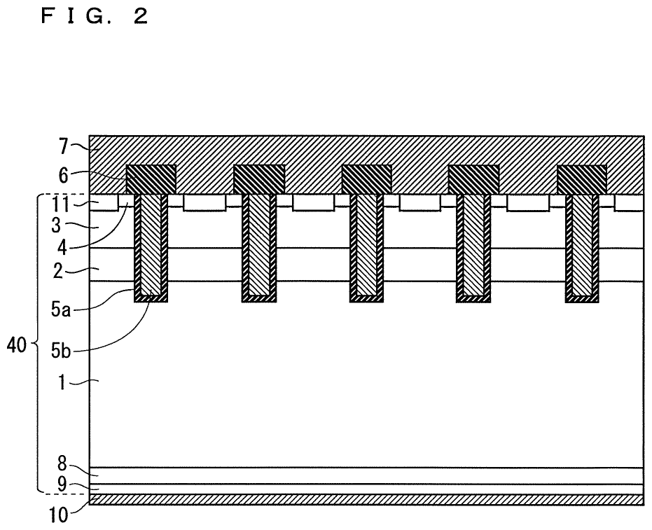

FIG. 2 is a cross-sectional view illustrating a structure of the IGBT according to the first preferred embodiment. That is, FIG. 2 is a cross-sectional view of a part of the cell region 31 illustrated in FIG. 1.

As illustrated in FIG. 2, the IGBT according to the first preferred embodiment is formed using a semiconductor substrate 40 on which a drift layer 1 of the N type is formed. Hereinafter, a front surface (an upper surface in FIG. 2) of the semiconductor substrate 40 is referred to as a “first main surface”, and a back surface (a lower surface in FIG. 2) of the semiconductor substrate 40 is referred to as a “second main surface”.

A base layer 3 of the P type is provided in a surface portion on the first main surface side of the semiconductor substrate 40. An emitter layer 4 of an N⁺ type having an impurity concentration higher than that of the drift layer 1 and a contact layer 11 of a P⁺ type having an impurity concentration higher than that of the base layer 3 are selectively provided in a surface portion of the base layer 3. A carrier storage layer 2 of the N type is provided below the base layer 3, that is, between the base layer 3 and the drift layer 1.

Trenches each of which passes through the emitter layer 4, the base layer 3, and the carrier storage layer 2 and reaches the drift layer 1 is formed in the first main surface of the semiconductor substrate 40. That is, the trench reaches a position deeper than the carrier storage layer 2. A gate insulating film 5a is formed on an inner surface of the trench. A gate electrode 5b is formed on the gate insulating film 5a so as to be buried in the trench. Since the trench is formed deeper than the carrier storage layer 2, a withstand voltage between a collector and an emitter can be stabilized.

An interlayer insulating film 6 is provided on the first main surface of the semiconductor substrate 40 so as to cover the gate electrode 5b, and an emitter electrode 7 is provided on the interlayer insulating film 6. A contact hole reaching the emitter layer 4 and the contact layer 11 is formed in the interlayer insulating film 6, and the emitter electrode 7 is connected to the emitter layer 4 and the contact layer 11 through the contact hole.

A buffer layer 8 of the N type (hereinafter referred to as a “phosphorus buffer layer 8”) into which phosphorus is implanted as an impurity is provided in a surface portion on the second main surface side of the semiconductor substrate 40, and a collector layer 9 of the P type is provided in a surface portion of the phosphorus buffer layer 8. That is, the phosphorus buffer layer 8 is provided between the drift layer 1 and the collector layer 9. A collector electrode 10 connected to the collector layer 9 is provided on the second main surface of the semiconductor substrate 40.

A peak concentration of impurities of the base layer 3 is set to approximately 8.0E16/cm³ to 5.0E17/cm³ such that a threshold voltage Vth of a gate when a current starts to flow from the collector to the emitter becomes about 6 V.

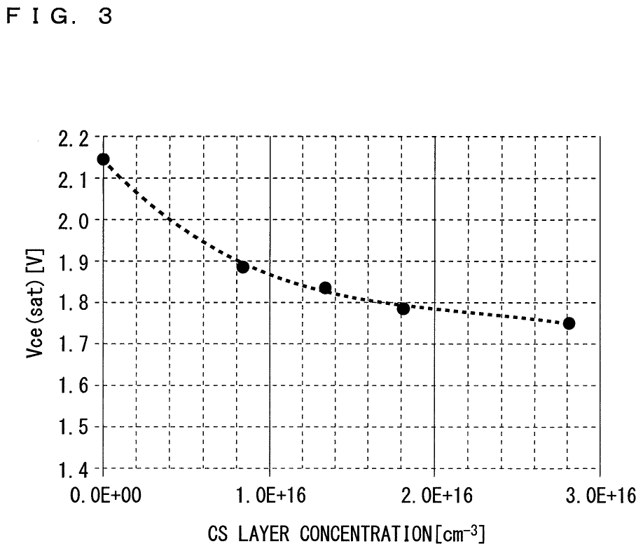

FIG. 3 is a view illustrating a relationship between an impurity concentration of the carrier storage layer 2 and a collector-emitter saturation voltage Vce (sat) of the IGBT. When the impurity concentration of the carrier storage layer 2 is increased, a potential barrier is formed between the drift layer 1 and the carrier storage layer 2, and an effect of storing holes from the second main surface of the semiconductor substrate 40 is enhanced so that a resistance of the drift layer 1 is reduced. Therefore, Vce (sat) can be decreased by increasing the concentration of the carrier storage layer 2 as illustrated in FIG. 3. However, merely increasing the concentration of the carrier storage layer 2 shortens a channel length so that a current flowing at the time of a short circuit increases, and thus, there is a concern about a decrease in short-circuit tolerance.

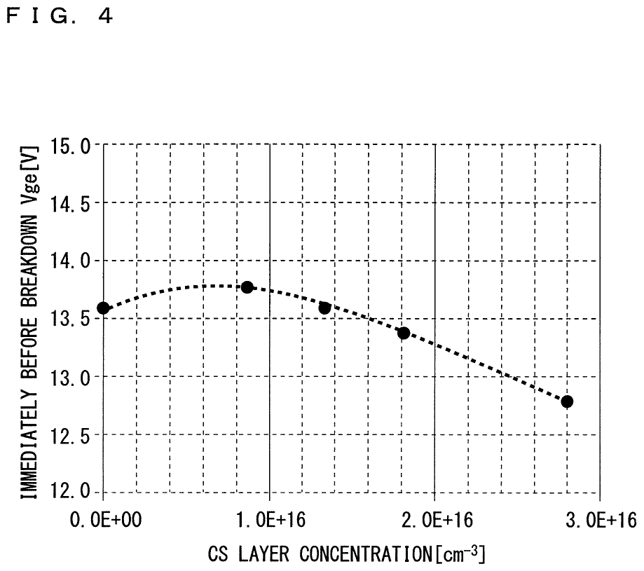

FIG. 4 is a view illustrating a relationship between the impurity concentration of the carrier storage layer 2 and a gate voltage Vge immediately before a breakdown of the IGBT in a short-circuit state (hereinafter, simply referred to as “gate voltage immediately before a breakdown”). Note that data as the basis of FIG. 4 is actual measurement values measured by increasing a gate voltage with time being fixed when the IGBT is short-circuited. A high gate voltage immediately before a breakdown corresponds to high short-circuit tolerance.

It can also be seen from FIG. 4 that increasing the impurity concentration of the carrier storage layer 2 decreases the short-circuit tolerance. However, it can be understood that it is possible to have short-circuit tolerance equal to or higher than that of an IGBT not including the carrier storage layer 2 (that is, a case where the impurity concentration of the carrier storage layer 2 is 0) if the impurity concentration of the carrier storage layer 2 is 1.4E16/cm³ or less. Therefore, the impurity concentration of the carrier storage layer 2 is set to 1.4E16/cm³ or less at least in a portion adjacent to the trench, that is, a portion immediately below a channel region where a channel is formed in the present preferred embodiment.

Here, a mechanism for improving the short-circuit tolerance when the impurity concentration of the carrier storage layer 2 is 1.4E16/cm³ or less will be considered. A diffusion potential Vbi at a PN junction between the carrier storage layer 2 and the base layer 3 is obtained by the following Formula (1).

$$\begin{matrix}[ Formula 1 ] & \\ {V}_{b i} = \frac{{k}_{B} T}{q} ln ( \frac{{N}_{A} {N}_{D}}{{n}_{i}^{2}} ) & ( 1 )\end{matrix}$$

In Formula (1), q represents an elementary charge, k_{B} represents a Boltzmann constant, T represents a temperature, N_{A} represents an acceptor density, N_{D} represents a donor density, and nᵢ represents an intrinsic carrier density. From Formula (1), it is considered that the diffusion potential increases when the impurity concentration of the carrier storage layer 2 increases, and the PN junction is hardly lost even if the temperature inside the semiconductor device rises during a short-circuit operation, so that the short-circuit tolerance is improved. This phenomenon is observed in a range where the impurity concentration of the carrier storage layer 2 is lower than 0.7E16/cm³ in a graph of FIG. 4. On the other hand, in a range in which the impurity concentration of the carrier storage layer 2 exceeds 0.7E16/cm³, the short-circuit tolerance is significantly reduced due to the above-described shortening of the channel length, so that the gate voltage immediately before a breakdown tends to decrease as the impurity concentration of the carrier storage layer 2 is increased. However, if the impurity concentration of the carrier storage layer 2 is suppressed to 1.4E16/cm³ or less, it is possible to suppress a decrease in the short-circuit tolerance due to the shortening of the channel length, and the short-circuit tolerance equal to or higher than that of an IGBT not including the carrier storage layer 2 is secured.

In the present exemplary preferred embodiment, the contact layer 11 is formed to be deeper than the emitter layer 4. Thus, a resistance of a hole current path from the second main surface of the semiconductor substrate 40 decreases, and improvement in the short-circuit tolerance is expected. Further, a voltage drop is suppressed, and an effect of preventing a latch-up operation of a parasitic transistor of the IGBT is also obtained.

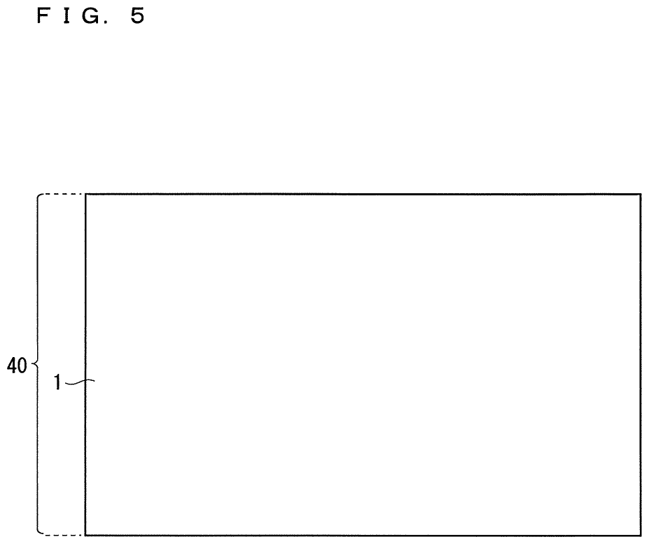

Here, a method of manufacturing the IGBT according to the first preferred embodiment will be described with reference to views of a process in FIGS. 5 to 15.

First, as illustrated in FIG. 5, the semiconductor substrate 40 of the N type to be the drift layer 1 is prepared. A specific resistance of the semiconductor substrate 40 is set to 20 Ω·cm or more and 100 Ω·cm or less, which is general as an in-vehicle product. A material of the semiconductor substrate 40 may be silicon or a wide band-gap semiconductor such as silicon carbide (SiC). A semiconductor device made of the wide band-gap semiconductor is excellent in operation at a high voltage, a large current, and a high temperature as compared with a conventional semiconductor device made of silicon. Examples of the wide band-gap semiconductor include gallium nitride (GaN)-based materials and diamond in addition to silicon carbide.

Next, in a region to be the termination region 34, a P-type impurity region to be the withstand voltage holding structure is formed to surround the cell region 31 by heat treatment at a high temperature for a long time.

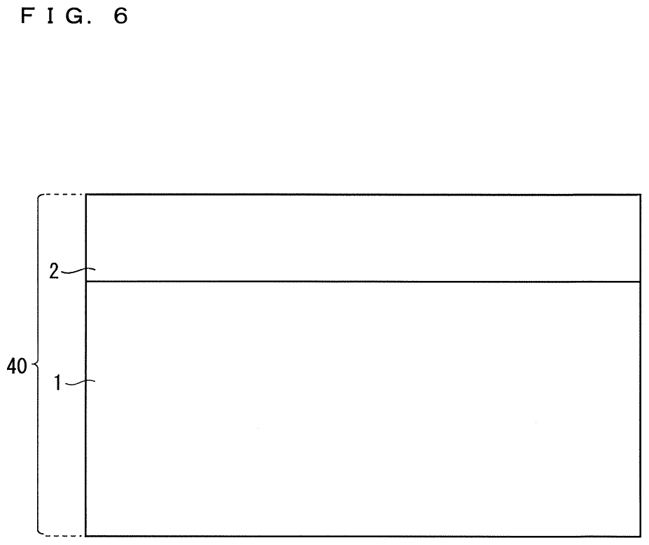

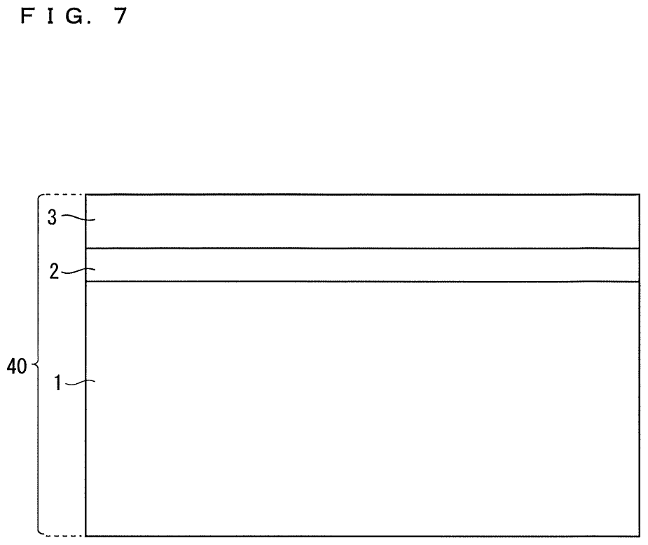

Thereafter, impurities are implanted into the first main surface of the semiconductor substrate 40 by selective ion implantation using a photolithography technique to form the carrier storage layer 2 and the base layer 3 in the surface portion on the first main surface side of the semiconductor substrate 40 as illustrated in FIGS. 6 and 7. At this time, in order to form the carrier storage layer 2 at a deeper position than the base layer 3, it is effective to implant phosphorus with high energy of MeV or to perform high-temperature drive after the implantation of phosphorus in the ion implantation for forming the carrier storage layer 2.

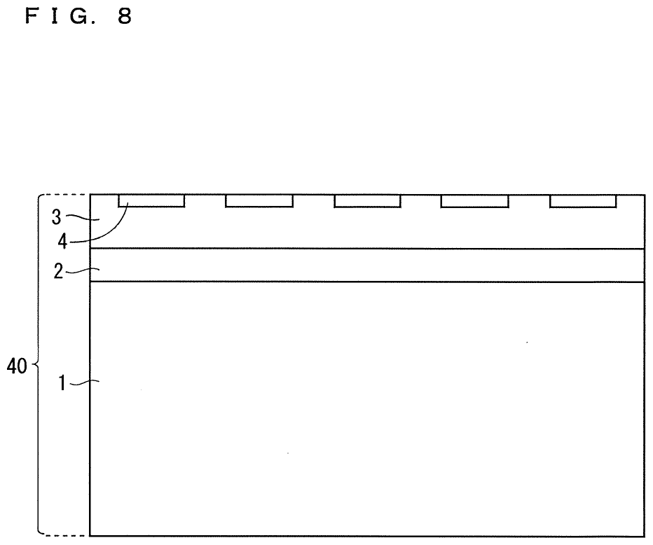

Next, as illustrated in FIG. 8, the emitter layer 4 is selectively formed in the surface portion of the base layer 3 by selective ion implantation of phosphorus or arsenic.

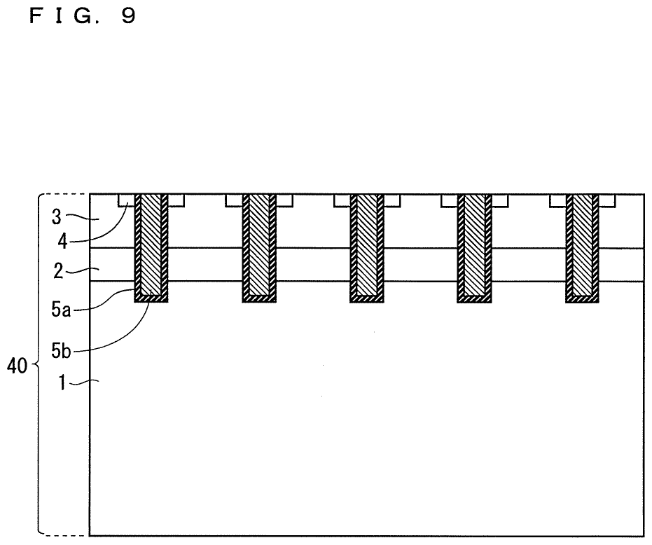

Subsequently, trenches passing through the emitter layer 4, the base layer 3, and the carrier storage layer 2 are formed in the first main surface of the semiconductor substrate 40 by selective dry etching using a photolithography technique. Then, as illustrated in FIG. 9, the gate insulating film 5a is formed on an inner surface of the trench by thermal oxidation or a chemical vapor deposition (CVD) method, and polysilicon is buried in the trench by the CVD method to form the gate electrode 5b.

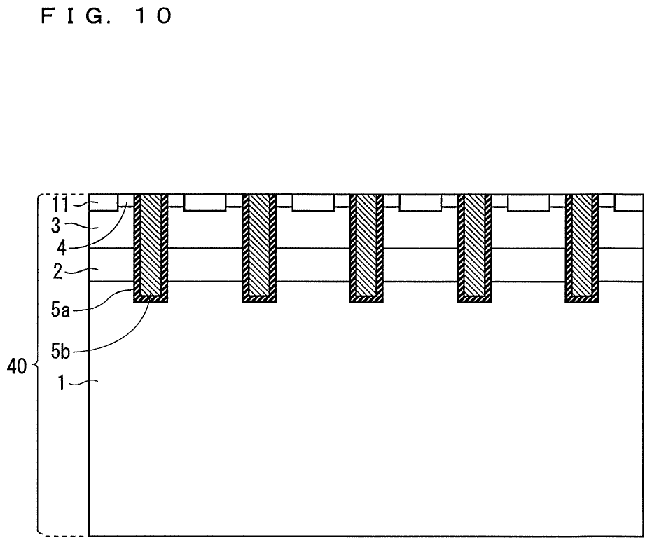

Thereafter, as illustrated in FIG. 10, the contact layer 11 is selectively formed in the surface portion of the base layer 3 by selective ion implantation. At this time, it is effective to implant boron with high energy or to perform high-temperature heat treatment in order to form the contact layer 11 to be deeper than the emitter layer 4. Note that the emitter layer 4 may be formed after the formation of the trenches.

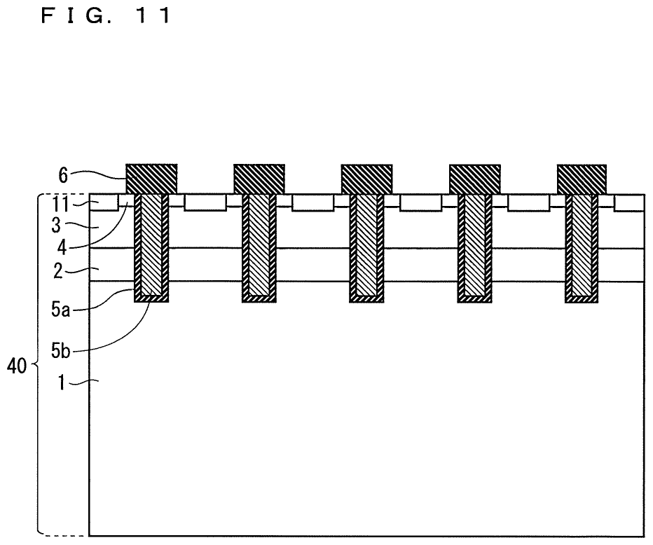

Next, as illustrated in FIG. 11, a TEOS oxide film, a BPTEOS oxide film (TEOS oxide film containing B and P as impurities), and the like are deposited to form the interlayer insulating film 6, and a contact hole reaching the emitter layer 4 and the contact layer 11 is formed in the interlayer insulating film 6 by selective etching. When the contact hole is formed by dry etching, an etching time may be set such that the first main surface of the semiconductor substrate 40 is slightly over-etched so as not to leave the interlayer insulating film 6 at a bottom of the contact hole. However, excessive over-etching leads to a loss of the emitter layer 4 and degradation in conduction capability, and thus, a depth of the over-etching with respect to the first main surface of the semiconductor substrate 40 is desirably shallower than a depth of the emitter layer 4. That is, a bottom of the emitter electrode 7 connected to the emitter layer 4 through the contact hole is desirably located to be shallower than a bottom of the emitter layer 4.

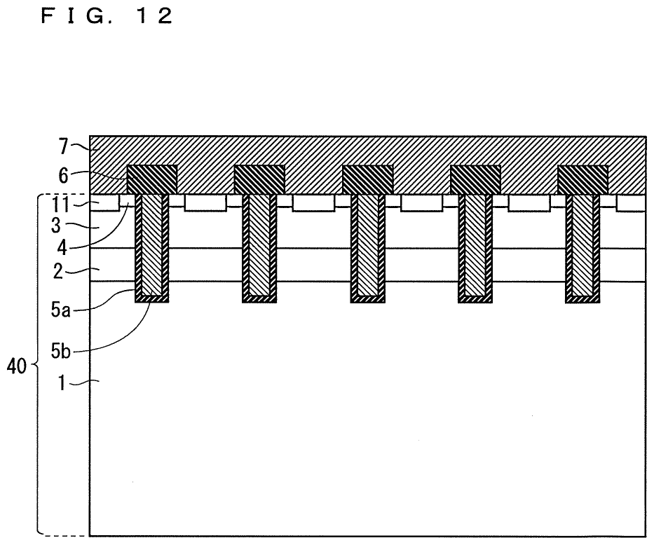

Next, metal of Al, AlSi, AlCu, or Cu is deposited by sputtering or vapor deposition to form the emitter electrode 7 on the interlayer insulating film 6 as illustrated in FIG. 12. At this time, the emitter electrode 7 is connected to the emitter layer 4 and the contact layer 11 through the contact hole formed in the interlayer insulating film 6. Furthermore, a protective film made of glass coating or polyimide may be formed on the emitter electrode 7 as necessary.

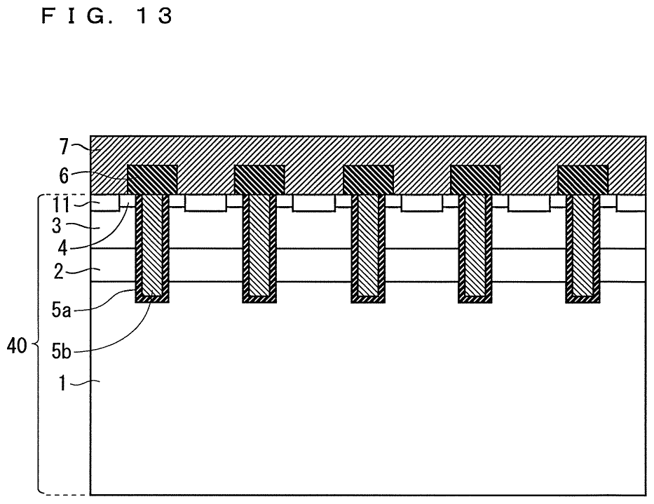

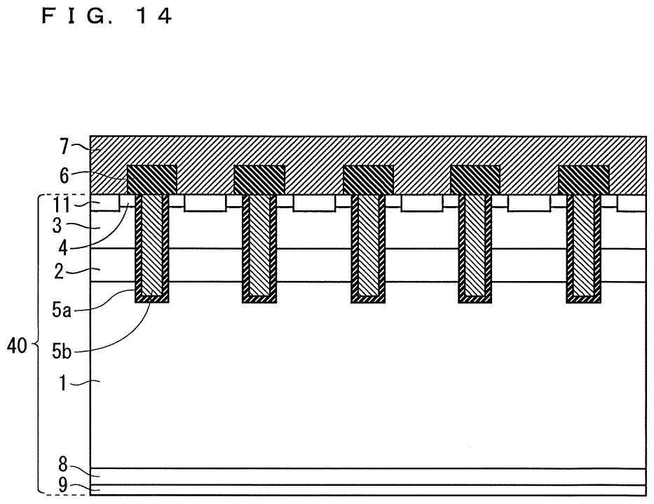

Thereafter, the second main surface side of the semiconductor substrate 40 is ground to thin the semiconductor substrate 40 as illustrated in FIG. 13. Then, the phosphorus buffer layer 8 and the collector layer 9 are formed in the surface portion on the second main surface side of the semiconductor substrate 40 by ion implantation of impurities into the second main surface of the semiconductor substrate 40 as illustrated in FIG. 14. At this time, ion implantation for forming the phosphorus buffer layer 8 is performed with high energy of several hundred keV to several MeV such that the phosphorus buffer layer 8 is formed at a deeper position than the collector layer 9. Thereafter, the impurities implanted into the semiconductor substrate 40 are activated by laser annealing or furnace annealing.

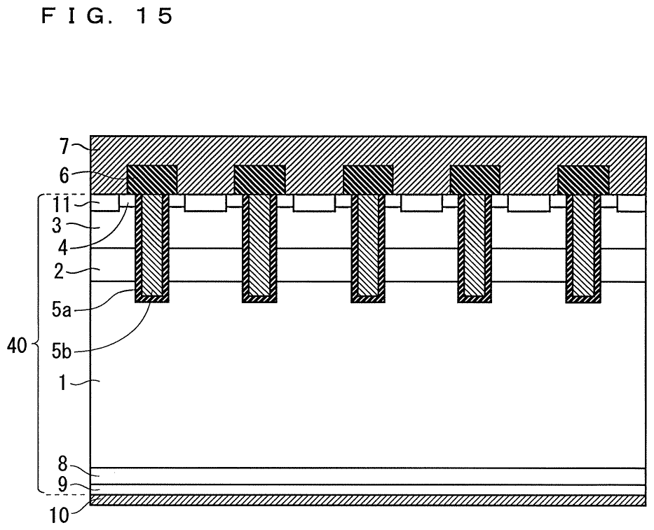

Finally, metal is deposited on the second main surface of the semiconductor substrate 40 by sputtering or vapor deposition to form the collector electrode 10 as illustrated in FIG. 15. The collector electrode 10 may have a laminated structure including a plurality of laminated films of ASi, Ti, Ni, Au, Ag, and the like in consideration of making contact with silicon having a high ohmic property or performing solder bonding.

### [Modifications]

In the first preferred embodiment, the semiconductor element formed in the cell region 31 is the IGBT. However, a semiconductor device may be a reverse conducting IGBT (RC-IGBT) including an IGBT and a diode connected in antiparallel to the IGBT.

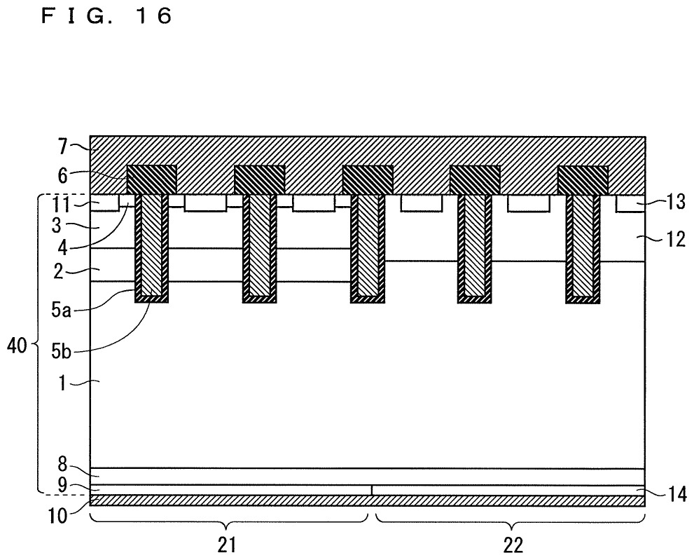

FIG. 16 is a cross-sectional view of an RC-IGBT as a modification of the first preferred embodiment. As illustrated in FIG. 16, the RC-IGBT includes an IGBT region 21 functioning as the IGBT and a diode region 22 functioning as the diode. A structure of the IGBT region 21 is the same as the structure of the IGBT illustrated in FIG. 2.

On the other hand, in the diode region 22, an anode layer 12 of the P type is formed on the carrier storage layer 2, that is, in the surface portion on the first main surface side of the semiconductor substrate 40. Further, a contact layer 13 of a P⁺ type having an impurity concentration higher than that of the anode layer 12 is formed in a surface portion of the anode layer 12. Since both the anode layer 12 and the contact layer 13 are P-type regions, these can be collectively referred to as an “anode layer”.

Further, a cathode layer 14 of the N type is formed in the surface portion on the second main surface side of the semiconductor substrate 40. Note that it is not necessary to provide the carrier storage layer 2 in the diode region 22.

In the diode region 22, the emitter electrode 7 is connected to the anode layer 12 and the contact layer 13 through the contact hole formed in the interlayer insulating film 6, and the collector electrode 10 is connected to the cathode layer 14. Thus, the diode in the diode region 22 and the IGBT in the IGBT region 21 are connected in anti-parallel.

In the RC-IGBT of FIG. 16, a trench is formed also in the diode region 22 as in the IGBT region 21 in order to stabilize a withstand voltage. However, a potential of an electrode formed in the trench of the IGBT region 21 is set to an emitter potential of the IGBT.

The anode layer 12 of the diode region 22 is formed to be deeper than the base layer 3 of the IGBT region 21 from the first main surface of the semiconductor substrate 40. In the IGBT having the carrier storage layer 2 under the base layer 3, an electric field increases in the lower part of the trench during a switching operation or a short-circuit operation, and dynamic avalanche occurs. At this time, when the anode layer 12 is deeper than the base layer 3, carriers are likely to escape to the diode side, and it is possible to prevent a breakdown of the element caused by the concentration of carriers on the IGBT side.

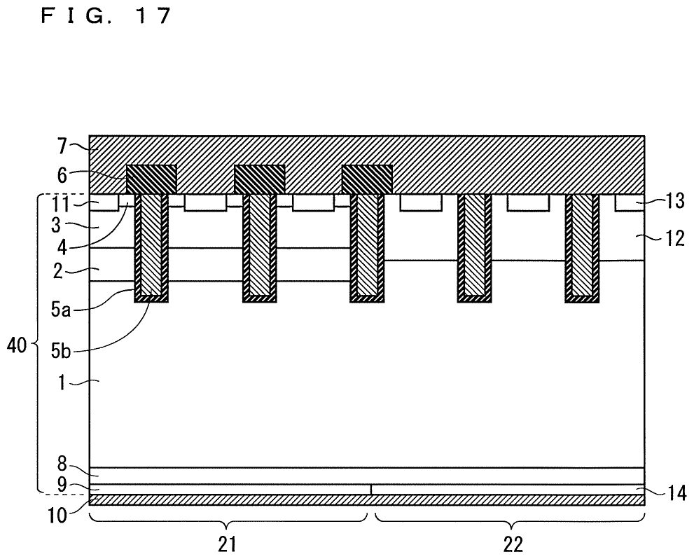

As illustrated in FIG. 17, the entire upper surface of the diode region 22 may be brought into contact with the emitter electrode 7 without forming the interlayer insulating film 6 in the diode region 22. This makes carriers are more likely to escape, which is effective for improving a breakdown resistance.

An impurity concentration of the anode layer 12 may be lower than that of the base layer 3. Then, it is possible to reduce a recovery loss of the diode while securing short-circuit tolerance.

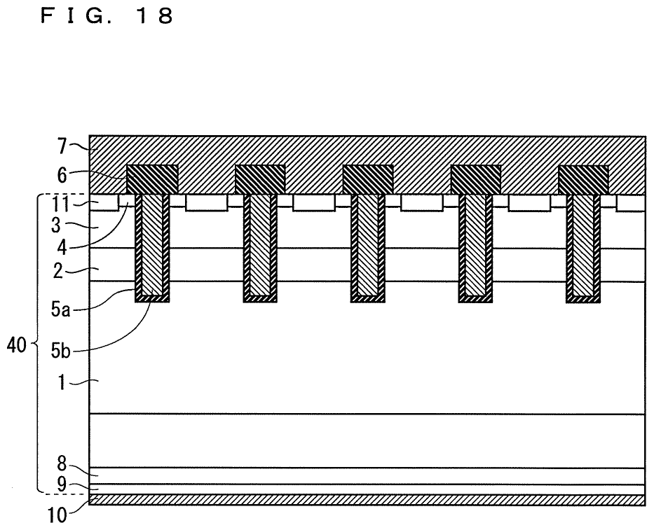

As illustrated in FIG. 18, a buffer layer 15 of the N type (hereinafter referred to as a “proton buffer layer 15”) into which protons are implanted as impurities may be provided between the drift layer 1 and the phosphorus buffer layer 8. Then, supply of holes from the second main surface of the semiconductor substrate 40 during the short-circuit operation is suppressed, concentration imbalance between electrons and holes is likely to occur, and the increase in the electric field on the first main surface side is suppressed, which is effective for improving the short-circuit tolerance. The proton buffer layer 15 can be formed by grinding the second main surface side of the semiconductor substrate 40, implanting protons, and converting the protons into donors by heat treatment at about 400° C.

Although FIG. 18 illustrates an example in which the proton buffer layer 15 is provided in the IGBT, the proton buffer layer 15 is also applicable to an RC-IGBT.

### Second Preferred Embodiment

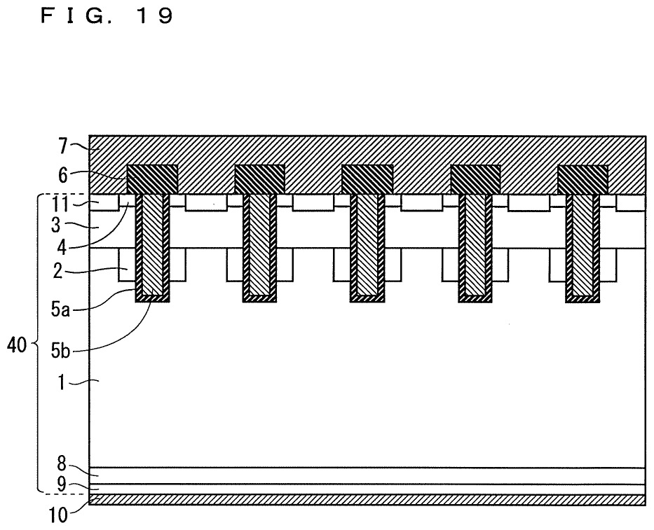

FIG. 19 is a cross-sectional view illustrating a structure of an IGBT according to a second preferred embodiment. As illustrated in FIG. 19, in the second preferred embodiment, the carrier storage layer 2 adjacent to each of trenches is locally provided in the vicinity of the trench in which the gate electrode 5b is buried, that is, only immediately below a channel region in which a channel is formed. The carrier storage layer 2 is not formed in a region other than the vicinity of the trench. The drift layer 1 or the trench is interposed between the adjacent carrier storage layers 2. In order to secure short-circuit tolerance of the IGBT, an impurity concentration of the carrier storage layer 2 is set to 1.4E16/cm³ or less at least in a portion adjacent to the trench.

According to the second preferred embodiment, Vce (sat) of the IGBT increases, but a turn-off loss Eoff is reduced as compared with the first preferred embodiment, so that the IGBT suitable for a high-speed operation can be obtained.

### [Modifications]

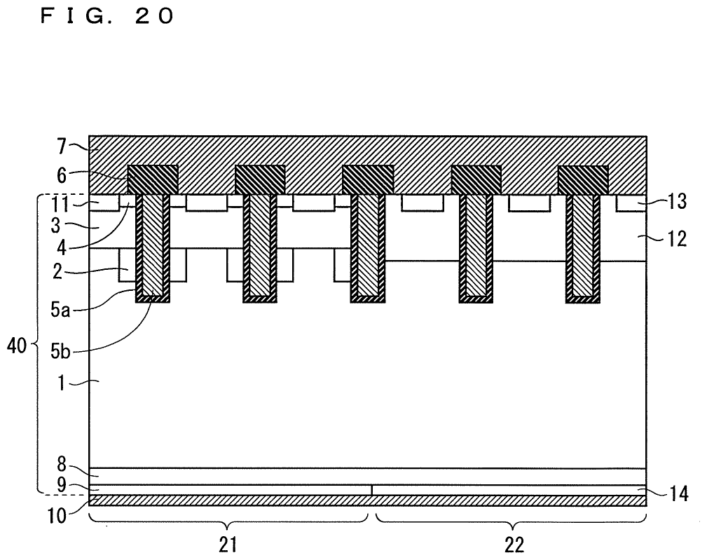

As illustrated in FIG. 20, the local carrier storage layer 2 described in the second preferred embodiment is also applicable to an RC-IGBT. In FIG. 20, the IGBT region 21 has the same structure as that of the IGBT of FIG. 19, and the diode region 22 has the same structure as that of the diode region 22 of FIG. 16.

### Third Preferred Embodiment

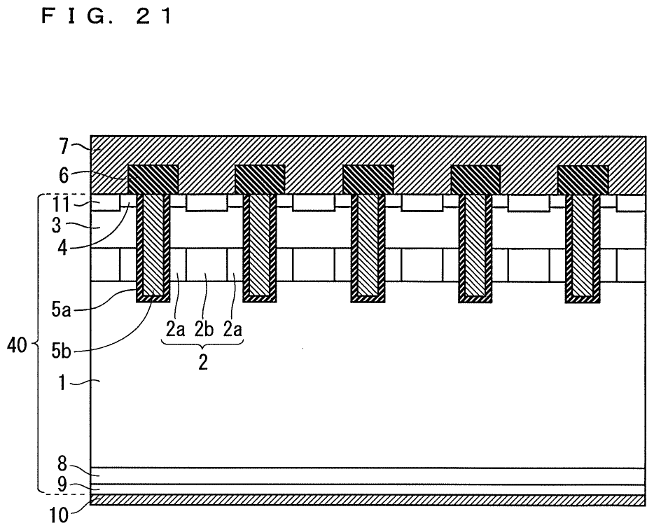

FIG. 21 is a cross-sectional view illustrating a structure of an IGBT according to a third preferred embodiment. As illustrated in FIG. 21, in the third preferred embodiment, the carrier storage layer 2 includes a first carrier storage layer 2a disposed in the vicinity of each of trenches in which the gate electrode 5b is buried, that is, immediately below a channel region, and a second carrier storage layer 2b disposed in a region between the first carrier storage layers 2a. An impurity concentration of the first carrier storage layer 2a is set to 1.4E16/cm³ or less, thereby securing short-circuit tolerance of the IGBT. An impurity concentration of the second carrier storage layer 2b is set to a value higher than that of the drift layer 1, thereby reducing Vce (sat) of the IGBT. The impurity concentration of the second carrier storage layer 2b may be higher or lower than the concentration of the first carrier storage layer 2a.

### [Modifications]

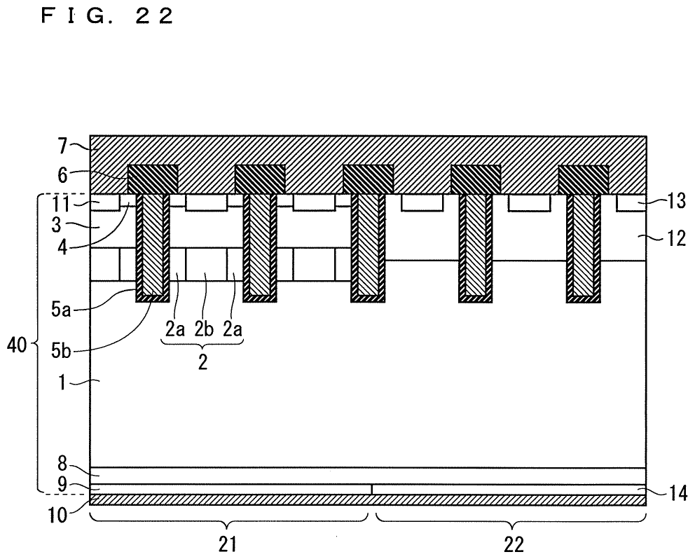

As illustrated in FIG. 22, the carrier storage layer 2 including the first carrier storage layer 2a and the second carrier storage layer 2b described in the third preferred embodiment is also applicable to an RC-IGBT. In FIG. 22, the IGBT region 21 has the same structure as that of the IGBT of FIG. 21, and the diode region 22 has the same structure as that of the diode region 22 of FIG. 16.

Note that each of the preferred embodiments can be freely combined, and each of the preferred embodiments can be appropriately modified or omitted.

### <Appendices>

Hereinafter, various aspects of the present disclosure will be collectively described as appendices.

### Appendix 1

A semiconductor device including:
a semiconductor substrate on which a drift layer of a first conductivity type is formed;
a base layer of a second conductivity type provided in a surface portion on a first main surface side of the semiconductor substrate;
an emitter layer of the first conductivity type which is selectively provided in the surface portion of the base layer and has an impurity concentration higher than an impurity concentration of the drift layer;
a contact layer of the second conductivity type which is selectively provided in the surface portion of the base layer and has an impurity concentration higher than an impurity concentration of the base layer;
a carrier storage layer of the first conductivity type which is provided between the base layer and the drift layer and has an impurity concentration higher than the impurity concentration of the drift layer;
a trench which is provided on the first main surface side of the semiconductor substrate and reaches a position deeper than the carrier storage layer;
a gate insulating film provided on an inner surface of the trench;
a gate electrode provided on the gate insulating film and buried in the trench; and
a collector layer of the second conductivity type provided in a surface portion on a second main surface side of the semiconductor substrate, wherein
a depth of the contact layer is deeper than a depth of the emitter layer, and
an impurity concentration of the carrier storage layer is 1.4E16/cm³ or less at least in a portion adjacent to the trench.

### Appendix 2

The semiconductor device according to Appendix 1, wherein the carrier storage layer is locally formed near the trench.

### Appendix 3

The semiconductor device according to Appendix 1, wherein the carrier storage layer includes:
first carrier storage layers each of which is disposed near the trench and has an impurity concentration of 1.4E16/cm³ or less; and
a second carrier storage layer which is disposed between the first carrier storage layers and has an impurity concentration higher than the impurity concentration of the drift layer.

### Appendix 4

The semiconductor device according to any one of Appendices 1 to 3, wherein a bottom of an emitter electrode connected to the emitter layer is located to be shallower than a bottom of the emitter layer.

### Appendix 5

The semiconductor device according to any one of Appendices 1 to 4, further including a diode region functioning as a diode, wherein
the diode region includes:
   the drift layer;
   an anode layer of the second conductivity type provided in the surface portion on the first main surface side of the semiconductor substrate; and
   a cathode layer of the first conductivity type provided in the surface portion on the second main surface side of the semiconductor substrate, and
the anode layer is formed to be deeper than the base layer from the first main surface of the semiconductor substrate.

### Appendix 6

The semiconductor device according to any one of Appendices 1 to 4, further including a diode region functioning as a diode, wherein
the diode region includes:
   the drift layer;
   an anode layer of the second conductivity type provided in the surface portion on the first main surface side of the semiconductor substrate; and
   a cathode layer of the first conductivity type provided in the surface portion on the second main surface side of the semiconductor substrate, and
the anode layer has an impurity concentration lower than the impurity concentration of the base layer.

### Appendix 7

The semiconductor device according to any one of Appendices 1 to 6, further including a buffer layer of the first conductivity type into which a proton is implanted as an impurity, the buffer layer being provided between the drift layer and the collector layer.

### Appendix 8

The semiconductor device according to any one of Appendices 1 to 7, wherein a specific resistance of the drift layer is 20 Ω·cm or more and 100 Ω·cm or less.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate on which a drift layer of a first conductivity type is formed;
a base layer of a second conductivity type provided in a surface portion on a first main surface side of the semiconductor substrate;
an emitter layer of the first conductivity type which is provided selectively in the surface portion of the base layer and has an impurity concentration higher than an impurity concentration of the drift layer;
a contact layer of the second conductivity type which is selectively provided in the surface portion of the base layer and has an impurity concentration higher than an impurity concentration of the base layer;
a carrier storage layer of the first conductivity type which is provided between the base layer and the drift layer and has an impurity concentration higher than the impurity concentration of the drift layer;
a trench which is provided on the first main surface side of the semiconductor substrate and reaches a position deeper than the carrier storage layer;
a gate insulating film provided on an inner surface of the trench;
a gate electrode provided on the gate insulating film and buried in the trench; and
a collector layer of the second conductivity type provided in a surface portion on a second main surface side of the semiconductor substrate, wherein
a depth of the contact layer is deeper than a depth of the emitter layer, and
the impurity concentration of the carrier storage layer is 1.4E16/cm³ or less at least in a portion adjacent to the trench.

2. The semiconductor device according to claim 1, wherein the carrier storage layer is locally formed near the trench.

3. The semiconductor device according to claim 1, wherein the carrier storage layer includes:
first carrier storage layers each of which is disposed near the trench and has an impurity concentration of 1.4E16/cm³ or less; and
a second carrier storage layer which is disposed between the first carrier storage layers and has an impurity concentration higher than the impurity concentration of the drift layer.

4. The semiconductor device according to claim 1, wherein a bottom of an emitter electrode connected to the emitter layer is located to be shallower than a bottom of the emitter layer.

5. The semiconductor device according to claim 1, further comprising a diode region functioning as a diode, wherein
the diode region includes:
the drift layer;
an anode layer of the second conductivity type provided in the surface portion on the first main surface side of the semiconductor substrate; and
a cathode layer of the first conductivity type provided in the surface portion on the second main surface side of the semiconductor substrate, and
the anode layer is formed to be deeper than the base layer from the first main surface of the semiconductor substrate.

6. The semiconductor device according to claim 1, further comprising a diode region functioning as a diode, wherein
the diode region includes:
the drift layer;
an anode layer of the second conductivity type provided in the surface portion on the first main surface side of the semiconductor substrate; and
a cathode layer of the first conductivity type provided in the surface portion on the second main surface side of the semiconductor substrate, and
the anode layer has an impurity concentration lower than the impurity concentration of the base layer.

7. The semiconductor device according to claim 1, further comprising a buffer layer of the first conductivity type into which a proton is implanted as an impurity, the buffer layer being provided between the drift layer and the collector layer.

8. The semiconductor device according to claim 1, wherein a specific resistance of the drift layer is 20 Ω·cm or more and 100 Ω·cm or less.
